(19) United States
(12) Patent Application Publication
(10) Pub. No.: US 2015/0059969 A1
(43) Pub. Date: Mar. 5, 2015

(54) METHOD OF LAMINATING SUBSTRATES AND METHOD OF MANUFACTURING FLEXIBLE DISPLAY APPARATUS BY USING THE METHOD OF LAMINATING SUBSTRATES

(71) Applicant: SAMSUNG DISPLAY CO., LTD., Yongin-City (KR)

(72) Inventor: Ji-Won Han, Yongin-City (KR)

(73) Assignee: SAMSUNG DISPLAY CO., LTD., Yongin-City (KR)

(21) Appl. No.: 14/272,391

(22) Filed: May 7, 2014

(30) Foreign Application Priority Data
Sep. 3, 2013 (KR) 10-2013-0105689

(51) Int. Cl. H01L 51/56; G02F 1/1333; B32B 37/12

(52) U.S. Cl. CPC H01L 51/56; B32B 37/12; G02F 1/133305
USPC 156/247; 156/329; 156/306.6

(57) ABSTRACT

A method of laminating substrates includes preparing a first substrate and a second substrate, forming a self-assembled monolayer on one surface of the first substrate, the self-assembled monolayer includes a region A including an alkyl chain and a region B including an alkyl chain having a carbon number less than a carbon number of the alkyl chain of the region A, and laminating the first substrate and the second substrate by contacting the self-assembled monolayer with the second substrate.

### CROSS-REFERENCE TO RELATED APPLICATION

This application claims priority to and the benefit of Korean Patent Application No. 10-2013-0105689, filed on Sep. 3, 2013 in the Korean Intellectual Property Office, the disclosure of which is incorporated herein in its entirety by reference.

### BACKGROUND

1. Field

One or more embodiments of the present invention relate to a method of laminating substrates and a method of manufacturing a flexible display apparatus by utilizing the method of laminating substrates.

2. Description of the Related Art

Substrates are used in various mechanical components, mechanical apparatuses, electronic devices, and electronic apparatuses. Also, in some cases, two substrates are arranged to face each other and then laminated.

When the two substrates are laminated together, the lamination characteristics of the surfaces of the two substrates are important. For example, if the two substrates have substantially similar or uniform characteristics, the lamination characteristics may be affected. In this situation, for lamination purposes, there is a need to improve the characteristics of the substrates, and for example, an adhesive material may be disposed between the two substrates.

When a flexible display apparatus is manufactured, it may be desirable to perform a lamination process of a substrate and another substrate supporting the substrate. The lamination process may contribute to reducing the failure occurrence during the process of manufacturing the flexible display apparatus.

### SUMMARY

Aspects of one or more embodiments of the present invention are directed toward a method of laminating substrates and a method of manufacturing a flexible display apparatus by utilizing the method of laminating substrates.

Additional aspects and characteristics will be set forth in part in the description which follows and, in part, will be apparent from the description, or may be learned by practice of the presented embodiments.

According to one or more embodiments of the present invention, a method of laminating substrates includes: preparing a first substrate and a second substrate; forming a self-assembled monolayer on one surface of the first substrate, the self-assembled monolayer including a region A including an alkyl chain and a region B including an alkyl chain having a carbon number less than a carbon number of the alkyl chain of the region A; and laminating the first substrate and the second substrate by contacting the self-assembled monolayer with the second substrate.

The region A and the region B may each include a head portion that is in contact with the one surface of the first substrate and the alkyl chain that is connected to the head portion.

The carbon number of the alkyl chain of the region A may be greater than the carbon number of the alkyl chain of the region B by about 10 or more.

The carbon number of the alkyl chain of the region A may be about 18, and the carbon number of the alkyl chain of the region B may be about 3.

The forming of the self-assembled monolayer may include forming a first self-assembled monolayer by utilizing a first raw material, and forming a second self-assembled monolayer by modifying the first self-assembled monolayer by utilizing a second raw material, after the formation of the first self-assembled monolayer.

The region A of the self-assembled monolayer may be formed by utilizing the first raw material, and the region B of the self-assembled monolayer may be formed by utilizing the second raw material.

The first raw material may be a solution, and the forming of the first self-assembled monolayer may include evaporating the first raw material, and the second raw material may be a solution and the forming of the second self-assembled monolayer may include evaporating the second raw material.

The first raw material and the second raw material may be a same kind of solution and may respectively include alkyl chains having different carbon numbers.

The forming of the self-assembled monolayer may include forming a third self-assembled monolayer by modifying the second self-assembled monolayer to have a hydrophilic surface by a hydrophilic treatment.

A hydrophilically treated surface may be formed on one surface of the second substrate, and the laminating of the first substrate and the second substrate may be performed by contacting the hydrophilically treated surface of the second substrate and the third self-assembled monolayer of the first substrate.

The laminating of the first substrate and the second substrate may include utilizing a support member that supports the first substrate and the second substrate, and applying pressure to the first substrate and the second substrate utilizing the support member.

According to one or more embodiments of the present invention, a method of manufacturing a flexible display apparatus includes: preparing a first substrate and a second substrate; forming a self-assembled monolayer on one surface of the first substrate, the self-assembled monolayer including a region A including an alkyl chain and a region B including an alkyl chain having a carbon number less than a carbon number of the alkyl chain of the region A; laminating the first substrate and the second substrate by contacting the self-assembled monolayer with the second substrate; and forming a display device on a surface of the first substrate opposite to a surface laminated with the second substrate.

The method may further include removing the second substrate from the first substrate after the formation of the display device.

The display device may include an organic light-emitting device.

The method may further include forming an encapsulation unit to cover the display device.

The region A and the region B may each include a head portion that is in contact with the one surface of the first substrate and the alkyl chain that is connected to the head portion.

The carbon number of the alkyl chain of the region A may be greater than the carbon number of the alkyl chain of the region B by about 10 or more.

The carbon number of the alkyl chain of the region A may be about 18, and the carbon number of the alkyl chain of the region B may be about 3.

The forming of the self-assembled monolayer may include forming a first self-assembled monolayer utilizing a first raw material, and forming a second self-assembled monolayer by modifying the first self-assembled monolayer utilizing a second raw material.

The region A of the self-assembled monolayer may be formed by utilizing the first raw material, and the region B of the self-assembled monolayer may be formed by utilizing the second raw material.

These general and specific embodiments may be implemented by utilizing a system, a method, a computer program, or a combination of the system, the method, and the computer program.

### BRIEF DESCRIPTION OF THE DRAWINGS

These and/or other aspects and characteristics will become apparent and more readily appreciated from the following description of the embodiments, taken in conjunction with the accompanying drawings in which:

FIGS. 1A through 1L are schematic views sequentially illustrating a method of laminating substrates according to an embodiment of the present invention; and

FIGS. 2A through 2J are schematic views sequentially illustrating a method of manufacturing a flexible display apparatus according to an embodiment of the present invention.

### DETAILED DESCRIPTION

Reference will now be made in detail to example embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Expressions such as “at least one of,” when preceding a list of elements, modify the entire list of elements and do not modify the individual elements of the list.

While the invention is amenable to various modifications and alternative forms, specific example embodiments have been shown by way of example in the drawings and are described in detail below. Features and characteristics of the present invention and implementation methods thereof will be clarified through the following embodiments described with reference to the accompanying drawings. The present invention may, however, be embodied in different forms and should not be construed as limited to the embodiments set forth herein.

Hereinafter, embodiments of the present invention will be described in more detail with reference to the accompanying drawings. Like reference numerals in the drawings denote like elements, and thus their description may be omitted.

It will be understood that although the terms “first”, “second”, etc. may be used herein to describe various components, these components should not be limited by these terms. These components are only used to distinguish one component from another.

As used herein, the singular forms “a”, “an”, and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, because sizes and thicknesses of components in the drawings may be arbitrarily illustrated for convenience of explanation, the following embodiments are not limited thereto.

In the following examples, the x-axis, the y-axis, and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed at substantially the same time or may be performed in an order opposite the described order.

Expressions, such as “at least one of,” when preceding a list of elements, modify the entire list of elements and do not modify the individual elements of the list. Further, the use of “may” when describing embodiments of the present invention refers to “one or more embodiments of the present invention.”

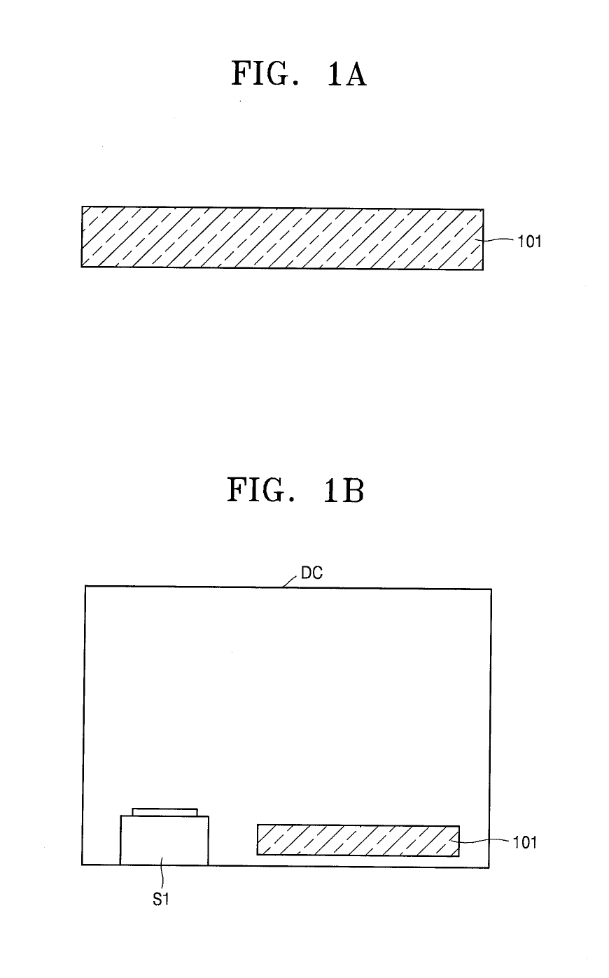

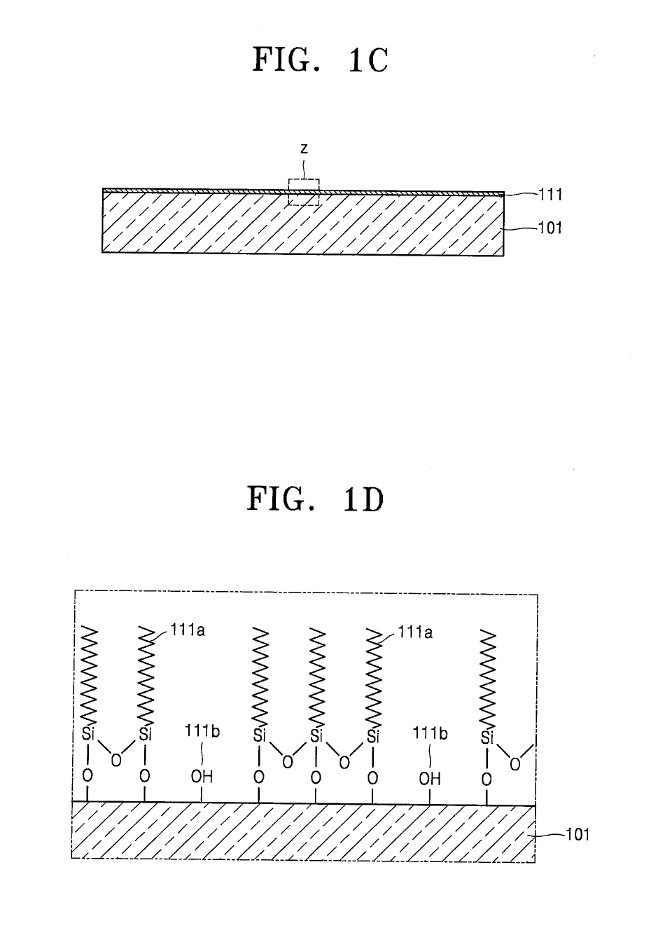

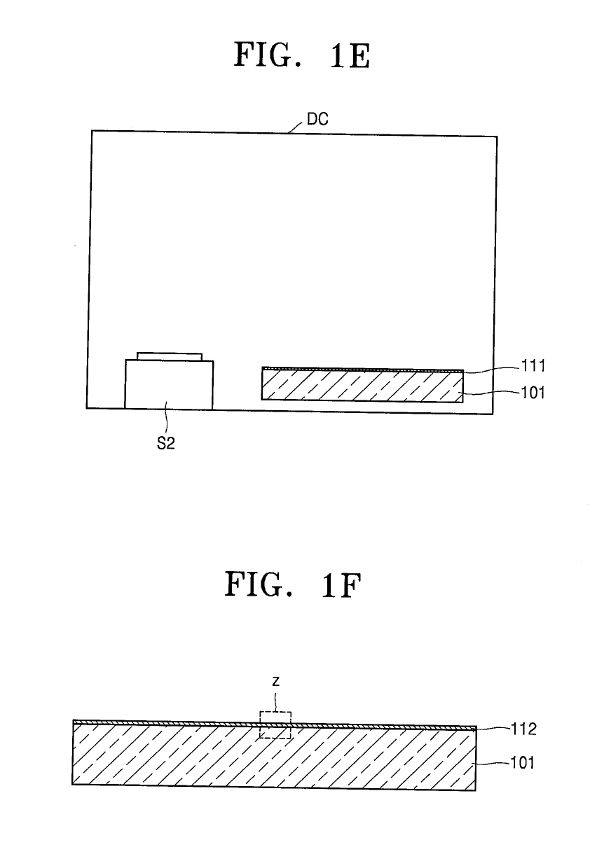

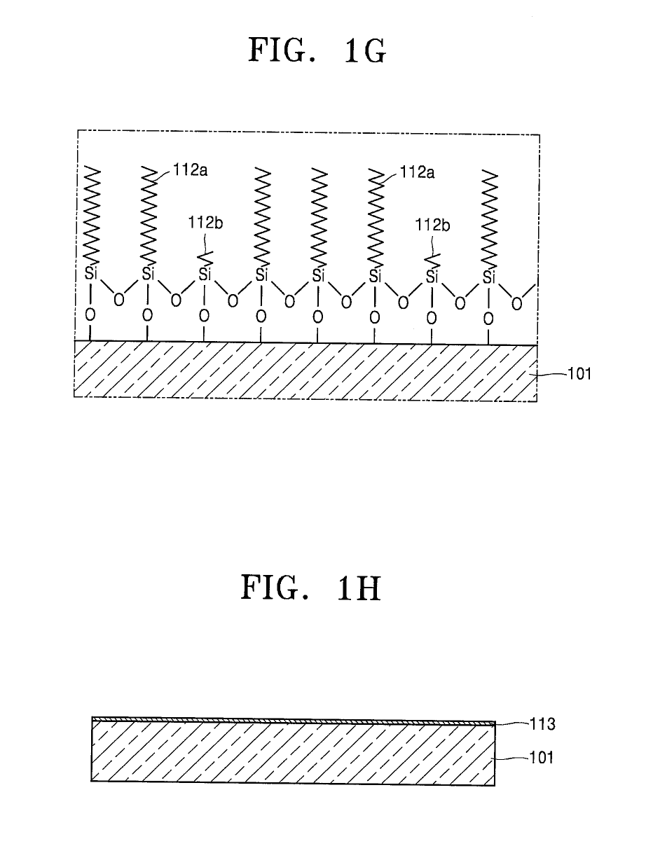

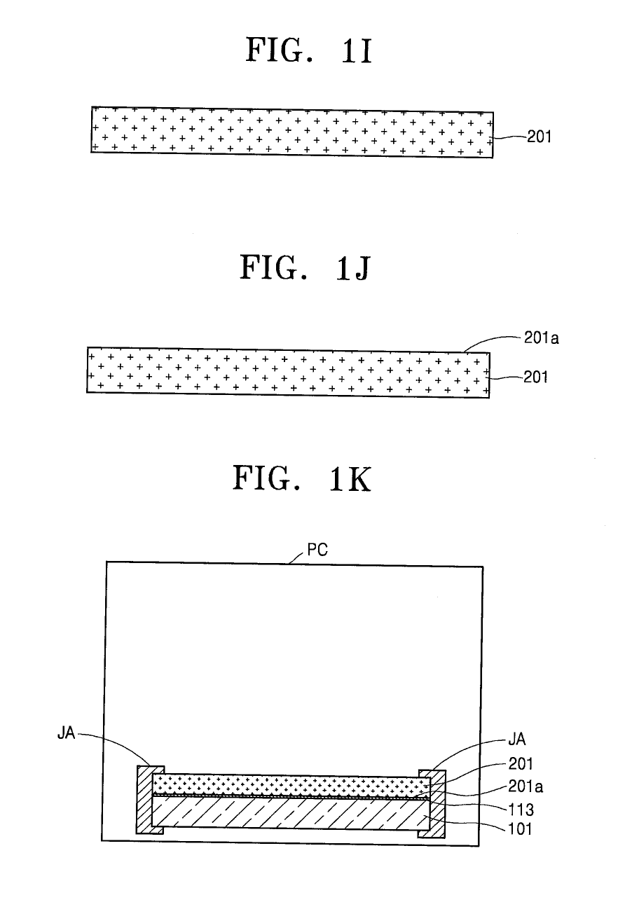

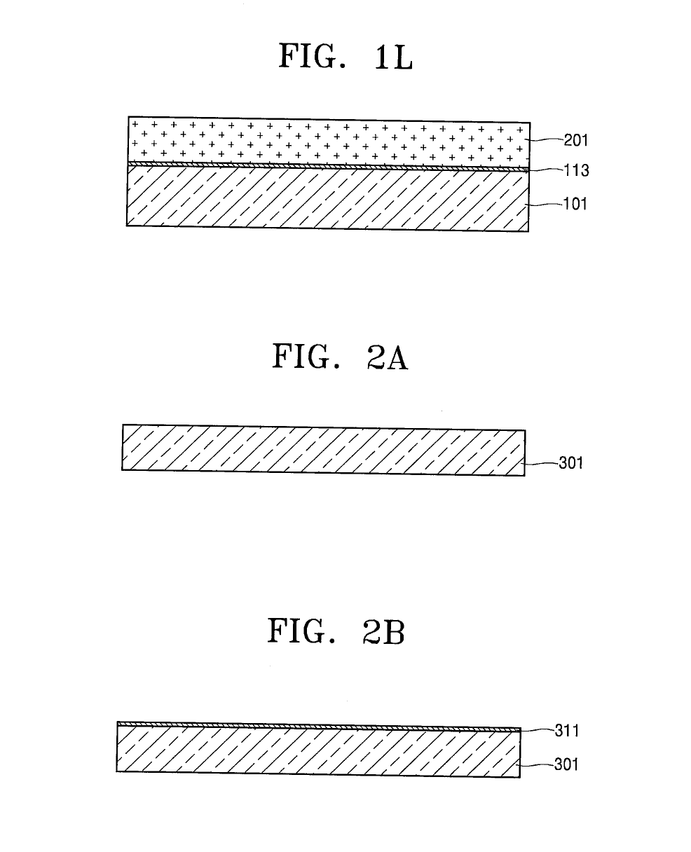

FIGS. 1A through 1L are schematic views sequentially illustrating a method of laminating substrates according to an embodiment of the present invention.

Referring to FIG. 1A, a first substrate 101 is prepared. The first substrate 101 may be formed of various materials. For example, the first substrate 101 may be formed of a glass material or a flexible plastic material.

In an example embodiment, a cleaning process may be further performed to remove foreign matter from a surface of the first substrate 101.

Thereafter, referring to FIG. 1B, a deposition chamber DC is prepared and the first substrate 101 is disposed in the deposition chamber DC. The deposition chamber DC may include one or more inlets and outlets for the entry and exit of the first substrate 101.

In an example embodiment, the first substrate 101 may be disposed on a stage in the deposition chamber DC.

A first raw material S1 is disposed in the deposition chamber DC. The first raw material S1 may include a solution for forming a self-assembled monolayer (SAM). For example, the first raw material S1 may include a silane solution having an alkyl group. For example, the silane solution having an alkyl group may include a solute composed of a head portion and a body portion. The head portion may contain silane, and the body portion may contain an alkyl chain (for example, an alkyl chain having a carbon number of about 18).

A deposition process is performed on the first substrate 101 by evaporating the first raw material S1 by heating the inside of the deposition chamber DC. The deposition chamber DC may be, for example, an electric furnace, but the present invention is not limited thereto.

A time period and temperature for heating the inside of the deposition chamber DC may be variously determined. For example, the first raw material S1 may be evaporated by heating the inside of the deposition chamber DC at about 150° C. for about 1 hour. The inside of the deposition chamber DC may be under an ambient atmosphere.

When the deposition process is performed on the first substrate 101 by the evaporating the first raw material S1 in the deposition chamber DC, a first self-assembled monolayer (SAM) 111 is formed on the first substrate 101 as illustrated in FIG. 1C. Because the first SAM 111 is a layer formed by evaporating the first raw material S1, the first SAM 111 includes substantially the same material as the first raw material S1. For example, the first SAM 111 may include the head portion containing silane and the body portion containing an alkyl chain.

The first SAM 111 is further described with reference to FIG. 1D. FIG. 1D is an enlarged view of the region “Z” of FIG. 1C.

Referring to FIGS. 1C and 1D, the first SAM 111 may include a region A 111a and a region B 111b. In the region A 111a, as illustrated in FIG. 1D, the head portion containing silane is in contact with the surface of the first substrate 101 and the body portion containing an alkyl chain having a carbon number of about 18 is connected to the head portion. A unit structure is a structure in which the body portion containing an alkyl chain is connected to the head portion, and the region A 111a includes a plurality of unit structures. The region B 111b is adjacent to the region A 111a and does not include an alkyl chain. The region B 111b may only include a hydroxyl group formed on the surface of the first substrate 101 by hydrolysis with moisture in the air.

That is, the region B 111b may be a void on the first substrate 101 formed during the formation of the first SAM 111. For example, when the first SAM 111 is formed, the head portions containing silane and the unit structures of the body portions connected thereto, which are included in region A 111a, may not form the first SAM 111 uniformly on the top surface of the first substrate 101 due to van der Waals forces therebetween, and thus, the region B 111b may be formed in the form of a void (e.g., the region B 111b may be a region where head portion containing silane and the unit structures of the body portions connected therefore do not form).

Thereafter, referring to FIG. 1E, the first substrate 101 having the first SAM 111 formed thereon is disposed in a deposition chamber DC. The first substrate 101 may be disposed on a stage in the deposition chamber DC. The deposition chamber DC in FIG. 1E may be the above-described deposition chamber DC in FIG. 1B. However, an embodiment of the present invention is not limited thereto, and a deposition chamber different from the deposition chamber DC of FIG. 1B may be used.

A second raw material S2 is disposed in the deposition chamber DC. The second raw material S2 may include a solution for forming a self-assembled monolayer (SAM). The second raw material S2 may include the same kind of solution as the first raw material S1. For example, the second raw material S2 includes a silane solution having an alkyl group. For example, the silane solution having an alkyl group included in the second raw material S2 includes a solute, and the solute is composed of a head portion and a body portion. The head portion may contain silane, and the body portion may contain an alkyl chain (for example, an alkyl chain having a carbon number of about 3).

A deposition process is performed on the first substrate 101 having the first SAM 111 formed thereon by evaporating the second raw material S2 by heating the inside of the deposition chamber DC. The deposition chamber DC may have various forms. For example, the deposition chamber DC may be an electric furnace.

A time period and temperature for heating the inside of the deposition chamber DC may be variously determined. For example, the second raw material S2 may be evaporated by heating the inside of the deposition chamber DC at about 150° C. for about 1 hour.

When the deposition process is performed on the first substrate 101 having the first SAM 111 formed thereon by the evaporation of the second raw material S2 in the deposition chamber DC, a second self-assembled monolayer (SAM) 112, which is formed by the modification of the first SAM 111, is formed on the first substrate 101 as illustrated in FIG. 1F.

The second SAM 112 is described with reference to FIG. 1G. FIG. 1G is an enlarged view of the region “Z” of FIG. 1F.

Referring to FIGS. 1F and 1G, the second SAM 112 includes a region A 112a and a region B 112b. The region A 112a may be substantially the same as the above-described region A 111a of the first SAM 111. For example, in the region A 112a, the head portion containing silane is in contact with the surface of the first substrate 101, and the body portion containing an alkyl chain having a carbon number of about 18 is connected to the head portion. The region A 112a includes a plurality of unit structures, wherein each of the unit structures is composed of the head portion and the body portion connected to the head portion. The region A 112a may not be affected by the second raw material S2. That is, the region A 112a may have a form in which the above-described region A 111a of the first SAM 111 remains substantially the same.

The region B 112b is adjacent to the region A 112a, wherein the region B 112b includes a head portion and a body portion, the head portion containing silane is in contact with the surface of the first substrate 101, and the body portion containing an alkyl chain having a carbon number of about 3 is connected to the head portion. That is, the region B 112b is formed to correspond to the region B 111b that exists in the form of a void after the forming of the first SAM 111 on the first substrate 101. That is, the above-described region B 111b in the form of a void is modified into the region B 112b, which includes the head portion containing silane and the body portion that is connected thereto and contains an alkyl chain having a carbon number of about 3, by utilizing the second raw material S2 during the forming of the second SAM 112.

In the present embodiment, the first raw material S1 and the second raw material S2 may be the same kind of material, (e.g., an alkyl silane solution) in which the head portion (containing silane) and the body portion (that is connected thereto and contains an alkyl chain) are included. Also, the alkyl chains respectively having a carbon number of about 18 and about 3 are described. However, this is only an example of the present embodiment, and the carbon numbers of the alkyl chains included in the first raw material S1 and the second raw material S2 may be variously determined. The carbon number of the alkyl chain included in the first raw material S1 may be greater than the carbon number of the alkyl chain included in the second raw material S2, wherein the carbon number of the alkyl chain included in the first raw material S1 may be greater than the carbon number of the alkyl chain included in the second raw material S2 by about 10 or more.

When the carbon number of the alkyl chain in the first raw material S1, which is to be used in a preceding process, is smaller than that of the alkyl chain in the second raw material S2, the region B 111b may not be completely filled even though a process utilizing the second raw material S2 is performed after the process utilizing the first raw material S1 is conducted. That is, because the van der Waals forces between the unit structures included in the second raw material S2 during the process utilizing the second raw material S2 increase, the region B 111b may not be completely filled. Similarly, when the carbon number of the alkyl chain in the first raw material S1 is not greater than that of the alkyl chain in the second raw material S2 or a difference therebetween is about 10 or less, the forming of the second SAM 112 having desired uniformity may not be facilitated due to the repulsive force between the alkyl chain included in the first raw material S1 and the alkyl chain included in the second raw material S2. Therefore, the carbon number of the alkyl chain included in the first raw material 51 may be greater than the carbon number of the alkyl chain included in the second raw material S2 by about 10 or more.

The second SAM 112 is formed on the first substrate 101 by the processes utilizing the first raw material S1 and the second raw material S2. The second SAM 112 is a self-assembled monolayer (SAM) that is formed by the two processes utilizing the two raw materials, i.e., a composite self-assembled monolayer. Thus, the carbon number of the alkyl chain formed in one region on the first substrate 101 may be different from the carbon number of the alkyl chain formed in another region on the first substrate 101. That is, the region A 112a includes the alkyl chain having a carbon number of about 18, and the region B 112b includes the alkyl chain having a carbon number of about 3. As a result, a self-assembled monolayer (SAM) may be formed (e.g., entirely formed) on the one surface of the first substrate 101 without a void.

Thereafter, referring to FIG. 1H, a third self-assembled monolayer (SAM) 113 having a hydrophilic surface may be formed by treating a surface of the second SAM 112 that is formed on the first substrate 101. The above-described second SAM 112 includes the region A 112a and the region B 112b as described in FIG. 1G. Ends of the second SAM 112, (e.g., ends of the region A 112a and the region B 112b) include a methyl group, which is an alkyl group. The ends of the second SAM 112, (e.g., the ends of the region A 112a and the region B 112b) are hydrophilically treated by a hydrophilic treatment. The hydrophilic treatment may be performed by irradiating laser or ultraviolet (UV) light. Thus, the ends of the region A 112a and the region B 112b or at least the end of the region A 112a may have hydrophilicity by including a hydroxyl group. As a result, the third SAM 113 having a hydrophilic surface may be formed on the first substrate 101.

Referring to FIG. 1I, a second substrate 201 may be prepared. The second substrate 201 may be formed of various materials. For example, the second substrate 201 may be formed of a glass material or a plastic material.

Referring to FIG. 1J, a hydrophilically treated surface 201a is then formed on one surface of the second substrate 201. The hydrophilically treated surface 201a may be formed by utilizing various methods, such as irradiating laser or UV light.

Thereafter, referring to FIG. 1K, a process of laminating the first substrate 101 and the second substrate 201 is performed. Specifically, the first substrate 101 and the second substrate 201 are disposed so that the third SAM 113 formed on the first substrate 101 and the hydrophilically treated surface 201a of the second substrate 201 are in contact with each other. In this case, in order to facilitate the lamination process, the first substrate 101 and the second substrate 201 may be supported and fixed by utilizing support members JA, and in an example embodiment, the lamination process of the first substrate 101 and the second substrate 201 may be facilitated by applying pressure through the support members JA. The support members JA may be disposed to correspond to sides of the first substrate 101 and a surface opposite to a surface facing the second substrate 201 among the surfaces of the first substrate 101, and to sides of the second substrate 201 and a surface opposite to a surface facing the first substrate 101 among the surfaces of the second substrate 201.

In an example embodiment, the lamination process may be performed in a lamination chamber PC in order to effectively perform the lamination process of the first substrate 101 and the second substrate 201. In this case, a temperature in the lamination chamber PC may be about 150° C., and the temperature may be maintained at about 150° C. for about 1 hour during the lamination process. Finally, as illustrated in FIG. 1L, a structure is completed, in which the first substrate 101 and the second substrate 201 are laminated while having the third SAM 113 disposed therebetween.

In the present embodiment, the first substrate 101 and the second substrate 201 are easily laminated by utilizing a SAM. For example, because the first SAM 111 is formed by utilizing the first raw material S1, and the second SAM 112 is then formed by utilizing the second raw material S2, a void may not be formed on the first substrate 101. Thus, penetration of moisture through the surface of the first substrate 101 may be substantially blocked. Also, because the third SAM 113 is formed by the hydrophilic treatment of the ends of the second SAM 112, the third SAM 113 may be easily combined with the hydrophilically treated surface 201a of the second substrate 201, and thus, the first substrate 101 and the second substrate 201 may be easily laminated.

In the laminated structure of the first substrate 101 and the second substrate 201, because the third SAM 113 covers (e.g., completely covers) the one surface of the first substrate 101, a void may not be formed and occurrence of a moisture trap due to the void may be reduced or prevented. Thus, the deformation of the laminated state of the first substrate 101 and the second substrate 201, which may occur due to the evaporation of moisture during a high-temperature process, may be substantially reduced or prevented.

For example, in the present embodiment, the first SAM 111 may be primarily formed on the first substrate 101 by utilizing the first raw material S1, and then, the second SAM 112 may be secondarily formed by utilizing the second raw material S2. Because the first SAM 111 is formed by utilizing the first raw material S1 that is substantially the same as the second raw material S2, (e.g., the solutions including alkyl silane) and a material of the second raw material S2 may rapidly react with the region B 111b corresponding to the void of the first SAM 111 in the process of utilizing the second raw material S2, the region B 112b filling the void may be easily formed.

Also, the first raw material S1 may contain an alkyl chain having a high carbon number, and the second raw material S2 may contain an alkyl chain having a low carbon number. A primary SAM including the first raw material S1 is formed on the first substrate 101 by forming the first SAM 111 utilizing the first raw material S1. Thereafter, because the second SAM 112, which is formed by filling the void of the first SAM 111, is formed by utilizing the second raw material S2, formation of a void that may occur on the surface of the first substrate 101 may be reduced or prevented.

For example, because the difference between the carbon number of the alkyl chain contained in the first raw material S1 and the carbon number of the alkyl chain contained in the second raw material S2 is relatively large, the material of the second material S2 may be easily moved and react with the region B 111b corresponding to the void of the first SAM 111 after the process of utilizing the first raw material S1 is performed. Thus, the region B 112b may be easily formed. For example, the carbon number of the alkyl chain contained in the first raw material S1 is, for example, about 18 and the carbon number of the alkyl chain contained in the second raw material S2 is, for example, about 3, and thus, the difference therebetween is about 10 or more. Therefore, the formation of voids including a hydroxyl group on the one surface of the first substrate 101 may be substantially reduced or prevented by reducing (e.g., minimizing) the interference between the alkyl chain contained in the first raw material S1 and the alkyl chain contained in the second raw material S2.

As a result, a stable lamination state of the first substrate 101 and the second substrate 201 may be maintained.

The method of laminating the first substrate 101 and the second substrate 201 according to the present example embodiment may be variously modified and used for various applications. For example, the method of laminating substrates of the present example embodiment may be used in a method of manufacturing a flexible display apparatus. This will be described in detail below.

However, this is only an example, and the method of laminating substrates according to the present embodiment may be applied in various suitable fields.

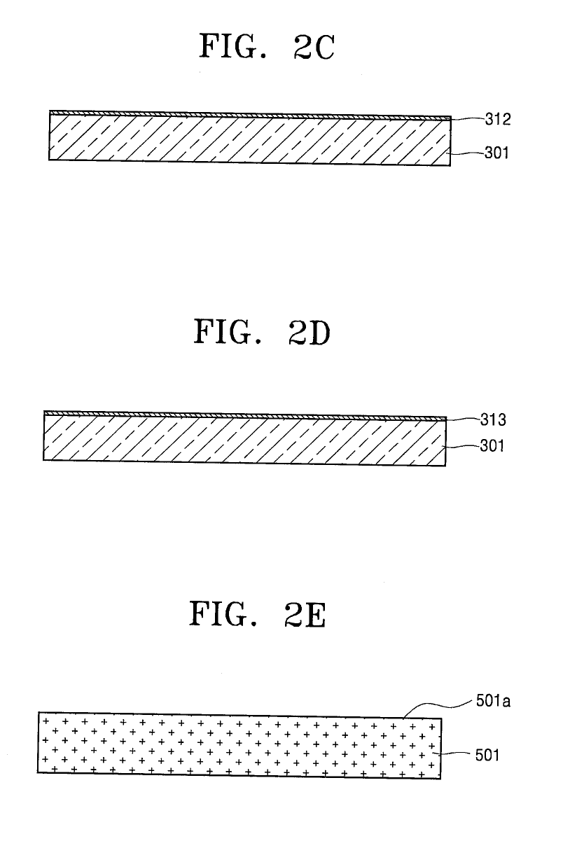

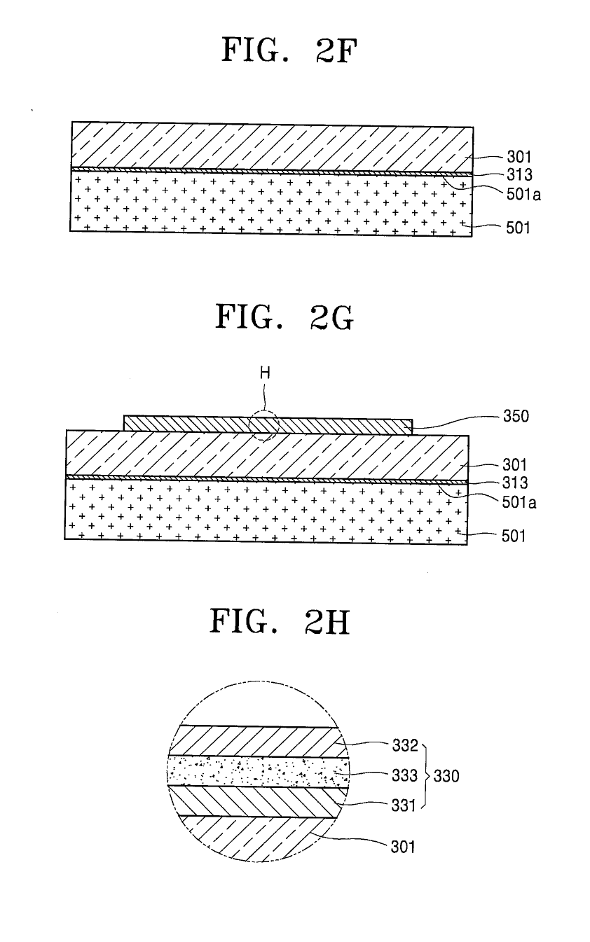

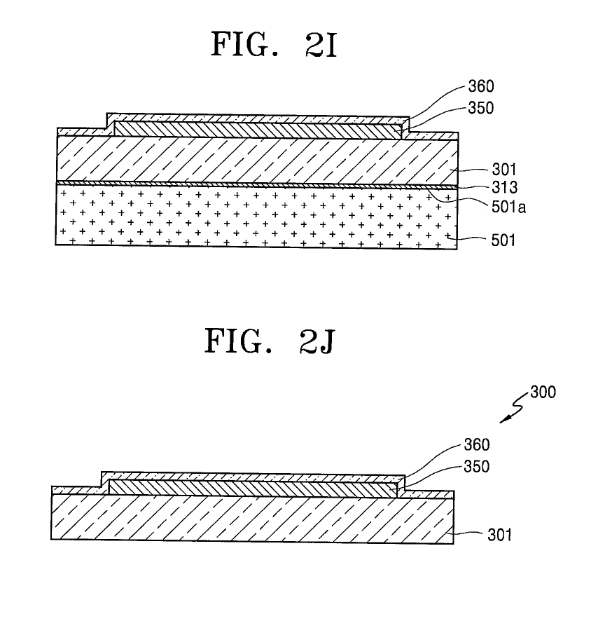

FIGS. 2A through 2J are schematic views sequentially illustrating a method of manufacturing a flexible display apparatus according to an example embodiment of the present invention.

Referring to FIG. 2A, a first substrate 301 is first prepared. The first substrate 301 may be formed of various materials. The first substrate 301 may be formed of a flexible material. For example, the first substrate 301 may be formed of a flexible glass material or a flexible plastic material.

In an example embodiment, a cleaning process may be further performed to remove foreign matter from a surface of the first substrate 301.

Then, referring to FIG. 2B, a first self-assembled monolayer (SAM) 311 is formed on the surface of the first substrate 301. The above method of laminating substrates may be used to form the first SAM 311. That is, the first SAM 311, as a layer formed by the evaporation of the above-described first raw material S1, contains a material of the first raw material S1. That is, the first SAM 311 includes a head portion containing silane and a body portion containing an alkyl chain. Also, the first SAM 311 includes a region A and a region B. In the region A, the head portion containing silane is in contact with the surface of the first substrate 301, and the body portion containing an alkyl chain having a carbon number of about 18 is connected to the head portion. Because the detailed description is substantially the same as the above-described embodiment, the description thereof is omitted.

Thereafter, referring to FIG. 2C, a second self-assembled monolayer (SAM) 312 is formed on the surface of the first substrate 301. A method of forming the second SAM 312 is substantially the same as the above-described method of laminating substrates. For example, the second SAM 312 is formed utilizing the second raw material S2, and in the second raw material S2, a head portion may contain silane and a body portion may include an alkyl chain, for example, an alkyl chain having a carbon number of about 3.

The second SAM 312 includes a region A and a region B. The region A is substantially the same as the above-described region A of the first SAM 311. The region B is adjacent to the region A, wherein the region B includes a head portion and a body portion, the head portion (containing silane) is in contact with the surface of the first substrate 301, and the body portion (containing an alkyl chain having a carbon number of about 3) is connected to the head portion. That is, the region B is formed to correspond to the region B that exists in the form of a void during the forming of the first SAM 311 on the first substrate 301. That is, the above-described region B in the form of a void may include the head portion (containing silane) and the body portion (that is connected thereto and contains an alkyl chain having a carbon number of about 3) by utilizing the second raw material S2 during the formation of the second SAM 312.

The second SAM 312 is formed on the first substrate 301 by utilizing the first raw material S1 and the second raw material S2. The second SAM 312 is a self-assembled monolayer (SAM) that is formed by the two processes utilizing the two raw materials, i.e., a composite self-assembled monolayer. Thus, the carbon number of the alkyl chain formed in one region is different from the carbon number of the alkyl chain formed in another region.

Thereafter, referring to FIG. 2D, a third self-assembled monolayer (SAM) 313 having a hydrophilic surface is formed by treating a surface of the second SAM 312 that is formed on the first substrate 301. Because the hydrophilic treatment for forming the third SAM 313 is substantially the same as in the above-described embodiment, a detailed description thereof is omitted.

Referring to FIG. 2E, a second substrate 501 is prepared. The second substrate 501 may be formed of various materials. For example, the second substrate 501 may be formed of a glass material or a plastic material. The second substrate 501 may be disposed to support the flexible first substrate 301. For this purpose, a strength of the second substrate 501 may be higher than that of the first substrate 301. Also, the second substrate 501 may be thicker than the first substrate 301.

A hydrophilically treated surface 501a may be formed on one surface of the second substrate 501. The hydrophilically treated surface 501a may be formed by utilizing various methods, such as irradiation of laser or UV light.

Then, referring to FIG. 2F, a process of laminating the first substrate 301 and the second substrate 501 may be performed. Specifically, the first substrate 301 and the second substrate 501 are laminated so that the third SAM 313 formed on the first substrate 301 and the hydrophilically treated surface 501a of the second substrate 501 are in contact with each other. Because a detailed description of the lamination process, i.e., a description of utilizing the support member and chamber, is substantially the same as in the above-described embodiment, the detailed description thereof is omitted.

Thereafter, referring to FIG. 2G, a display unit 350 is formed on one surface of the first substrate 301 (e.g., a surface of the first substrate 301 which is opposite the surface that is laminated with the second substrate 501 among the surfaces of the first substrate 301). The display unit 350 may include various kinds of display devices. For example, the display unit 350 may include an organic light-emitting device. However, this is only an example, and the display unit 350 may include a liquid crystal display device and other various display devices.

FIG. 2H is an enlarged view of the region “H” of FIG. 2G. In the present example embodiment, the display unit 350 includes an organic light-emitting device 330.

The organic light-emitting device 330 may be formed on the first substrate 301 and includes a first electrode 331, a second electrode 332, and an intermediate layer 333. For example, the first electrode 331 may be formed on the substrate 301, the second electrode 332 may be formed on the first electrode 331, and the intermediate layer 333 may be formed between the first electrode 331 and the second electrode 332.

A buffer layer may be further formed on the first electrode 331 and the first substrate 301.

The first electrode 331 may function as an anode, and the second electrode 332 may function as a cathode. However, the polarities of the first electrode 331 and the second electrode 332 may be reversed.

If the first electrode 331 functions as an anode, the first electrode 331 may include a high work function material, such as, for example, indium tin oxide (e.g., ITO), indium zinc oxide (e.g., IZO), zinc oxide (e.g., ZnO), and indium oxide (e.g., In₂O₃). Also, the first electrode 331 may further include a reflective layer formed of, for example, silver (Ag), magnesium (Mg), aluminium (Al), platinum (Pt), palladium (Pd), gold (Au), nickel (Ni), neodymium (Nd), iridium (Ir), chromium (Cr), lithium (Li), ytterbium (Yb), or calcium (Ca) according to purpose and design conditions.

If the second electrode 332 functions as a cathode, the second electrode 332 may be formed of a metal, such as, for example, Ag, Mg, Al, Pt, Pd, Au, Ni, Nd, Ir, Cr, Li, or Ca. Also, the second electrode 332 may include, for example, ITO, IZO, ZnO, and In₂O₃ so as to be transparent to light.

The intermediate layer 333 may include at least an organic emission layer. Also, the intermediate layer 333 may include (e.g., selectively include) at least one or more of a hole injection layer, a hole transport layer, an electron transport layer, and an electron injection layer in addition to the organic emission layer.

Although not shown in FIG. 2H, the present embodiment may further include forming one or more thin film transistors that are electrically connected to the organic light-emitting device 330. As another example, the present embodiment may further include forming one or more capacitors that are electrically connected to the organic light-emitting device 330.

Then, referring to FIG. 2I, an encapsulation unit 360 may be formed to cover the display unit 350. The encapsulation unit 360 may have various forms such as a thin film to cover the display unit 350. The encapsulation unit 360 may be formed of various materials. For example, the encapsulation unit 360 may be formed by utilizing an organic layer and/or an inorganic layer. Also, the encapsulation unit 360 may be formed by stacking (e.g., alternately stacking) one or more organic layers and one or more inorganic layers.

Thereafter, referring to FIG. 2J, a flexible display apparatus 300 is completed by removing the second substrate 501 from the first substrate 301. A process of removing the second substrate 501 from the first substrate 301 may be performed by utilizing various methods. For example, the second substrate 501 may be delaminated from the first substrate 301 by utilizing a physical method by disposing a separation member between the first substrate 301 and the second substrate 501.

In the present embodiment, the first substrate 301 and the second substrate 501 are easily laminated by utilizing a self-assembled monolayer (SAM). For example, because the first SAM 311 is formed by utilizing the first raw material S1 and the second SAM 312 is then formed by utilizing the second raw material S2, a void may not be formed on the first substrate 301. Thus, penetration of moisture through the surface of the first substrate 301 may be substantially reduced or blocked. Also, because the third SAM 313 is formed by the hydrophilic treatment of the ends of the second SAM 312, the third SAM 313 may be easily combined with the hydrophilically treated surface 501a of the second substrate 501. Thus, the first substrate 301 and the second substrate 501 may be easily laminated. Therefore, deformation of the flexible first substrate 301 during the forming of the display unit 350 on the first substrate 301 and failure of the display unit 350 due to the deformation of the first substrate 301 may be reduced or prevented by the lamination.

In the laminated structure of the first substrate 301 and the second substrate 501, because the third SAM 313 covers (e.g., completely covers) the one surface of the first substrate 301, a void may not be formed and occurrence of a moisture trap due to the void may be prevented. Thus, the deformation of the laminated state of the first substrate 301 and the second substrate 501, which may occur due to the evaporation of moisture during a high-temperature process, may be substantially reduced or prevented. Also, the forming of the display unit 350 may not be affected by moisture.

Thus, the manufacturing characteristics of the flexible display apparatus 300 may be improved, and the flexible display apparatus 300 having improved picture quality characteristics and higher failure prevention rate may be easily manufactured.

As described above, according to the one or more of the above embodiments of the present invention, a method of laminating substrates and a method of manufacturing a flexible display apparatus by utilizing the method of laminating substrates may easily improve the lamination characteristics of two substrates.

It should be understood that the example embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims and their equivalents.

What is claimed is:

1. A method of laminating substrates, the method comprising:
preparing a first substrate and a second substrate;
forming a self-assembled monolayer on one surface of the first substrate, the self-assembled monolayer comprising a region A comprising an alkyl chain and a region B comprising an alkyl chain having a carbon number less than a carbon number of the alkyl chain of the region A; and
laminating the first substrate and the second substrate by contacting the self-assembled monolayer with the second substrate.

2. The method of claim 1, wherein each of the region A and the region B comprises a head portion that is in contact with the one surface of the first substrate and the alkyl chain that is connected to the head portion.

3. The method of claim 1, wherein the carbon number of the alkyl chain of the region A is greater than the carbon number of the alkyl chain of the region B by about 10 or more.

4. The method of claim 1, wherein the carbon number of the alkyl chain of the region A is about 18, and the carbon number of the alkyl chain of the region B is about 3.

5. The method of claim 1, wherein the forming of the self-assembled monolayer comprises:
forming a first self-assembled monolayer by utilizing a first raw material; and
forming a second self-assembled monolayer by modifying the first self-assembled monolayer utilizing a second raw material.

6. The method of claim 5, wherein the region A of the self-assembled monolayer is formed by utilizing the first raw material, and the region B of the self-assembled monolayer is formed by utilizing the second raw material.

7. The method of claim 5, wherein the first raw material is a solution, and the forming of the first self-assembled monolayer comprises evaporating the first raw material, and
the second raw material is a solution and the forming of the second self-assembled monolayer comprises evaporating the second raw material.

8. The method of claim 5, wherein the first raw material and the second raw material are a same kind of solution and respectively comprise alkyl chains having different carbon numbers.

9. The method of claim 5, wherein the forming of the self-assembled monolayer further comprises forming a third self-assembled monolayer by modifying the second self-assembled monolayer to have a hydrophilic surface by a hydrophilic treatment.

10. The method of claim 9, wherein a hydrophilically treated surface is formed on one surface of the second substrate, and the laminating of the first substrate and the second substrate is performed by contacting the hydrophilically treated surface of the second substrate and the third self-assembled monolayer of the first substrate.

11. The method of claim 1, wherein the laminating of the first substrate and the second substrate comprises utilizing a support member that supports the first substrate and the second substrate, and applying pressure to the first substrate and the second substrate utilizing the support member.

12. A method of manufacturing a flexible display apparatus, the method comprising:
preparing a first substrate and a second substrate;
forming a self-assembled monolayer on one surface of the first substrate, the self-assembled monolayer comprising a region A comprising an alkyl chain and a region B comprising an alkyl chain having a carbon number less than a carbon number of the alkyl chain of the region A;
laminating the first substrate and the second substrate by contacting the self-assembled monolayer with the second substrate; and
forming a display device on a surface of the first substrate opposite to a surface laminated with the second substrate.

13. The method of claim 12, further comprising removing the second substrate from the first substrate after the forming of the display device.

14. The method of claim 12, wherein the display device comprises an organic light-emitting device.

15. The method of claim 12, further comprising forming an encapsulation unit to cover the display device.

16. The method of claim 12, wherein each of the region A and the region B comprises a head portion that is in contact with the one surface of the first substrate and the alkyl chain that is connected to the head portion.

17. The method of claim 12, wherein the carbon number of the alkyl chain of the region A is greater than the carbon number of the alkyl chain of the region B by about 10 or more.

18. The method of claim 12, wherein the carbon number of the alkyl chain of the region A is about 18, and the carbon number of the alkyl chain of the region B is about 3.

19. The method of claim 12, wherein the forming of the self-assembled monolayer comprises:
forming a first self-assembled monolayer utilizing a first raw material; and
forming a second self-assembled monolayer by modifying the first self-assembled monolayer utilizing a second raw material.

20. The method of claim 19, wherein the region A of the self-assembled monolayer is formed by utilizing the first raw material, and the region B of the self-assembled monolayer is formed by utilizing the second raw material.
